(19) United States
(12) Patent Application Publication
(10) Pub. No.: US 2026/0082951 A1
(43) Pub. Date: Mar. 19, 2026

(54) SEMICONDUCTOR PACKAGE STRUCTURE

(71) Applicant: CXMT Corporation, Hefei (CN)

(72) Inventor: Kaimin Lv, Hefei (CN)

(73) Assignee: CXMT Corporation, Hefei (CN)

(21) Appl. No.: 19/403,520

(22) Filed: Nov. 28, 2025

Related U.S. Application Data
(63) Continuation of application No. PCT/CN2023/131342, filed on Nov. 13, 2023.

(30) Foreign Application Priority Data
Jul. 3, 2023 (CN) 202310815386.0

(51) Int. Cl. H10W 70/60; H10B 80/00

(52) U.S. Cl. CPC H10W 70/611; H10B 80/00; H10W 29/00; H10W 90/10; H10W 90/297

(57) ABSTRACT

Disclosed is a semiconductor package structure, which includes a first substrate, a second substrate, a processor module, a chip stack structure, and a signal adapter board. The processor module is arranged on a first plane of the first substrate and connected to the first substrate; the chip stack structure is arranged on the first plane of the first substrate and connected to the first substrate, and the first substrate is configured to transmit a first-type signal between the processor module and the chip stack structure; the signal adapter board is connected to the processor module and the chip stack structure, and is configured to transmit a second-type signal between the processor module and the chip stack structure; and the second substrate is arranged parallel to the first substrate and connected to a second plane of the first substrate, and the second plane of the first substrate is parallel to and opposite to the first plane of the first substrate.

### CROSS-REFERENCE TO RELATED APPLICATIONS

This application is a continuation application of International Patent Application No. PCT/CN2023/131342, filed on Nov. 13, 2023, which claims the benefit of Chinese Patent Application No. 202310815386.0, titled “SEMICONDUCTOR PACKAGE STRUCTURE” , filed with the China National Intellectual Property Administration (CNIPA) on Jul. 3, 2023, the disclosures of which are incorporated herein by reference in their entireties.

### TECHNICAL FIELD

The present disclosure relates to the field of integrated circuit manufacturing technologies, and in particular, to a semiconductor package structure.

### BACKGROUND

High bandwidth memory (High Bandwidth Memory, HBM) technology is a high-bandwidth memory technology that uses 3D stacking technology to vertically stack a plurality of DRAM chips together and connect them through a through silicon via to form a high-density and high-bandwidth memory module.

With the advancement of process technology, the size of highly integrated HBM is becoming larger. Correspondingly, the size of processors such as the graphics processing unit (Graphics Processing Unit, GPU) connected to the HBM is also increasing, and the chip size of the silicon interposer (silicon interposer) configured to connect the HBM and the processor is also increasing. The increase in the size of the silicon interposer brings a significant increase in production difficulty and production costs.

It should be noted that the information disclosed in the above background section is only used for the enhancement of understanding of the background of the present disclosure, and therefore, may include information that does not constitute the prior art known to those of ordinary skill in the art.

### SUMMARY

An objective of the present disclosure is to provide a semiconductor package structure.

According to a first aspect of the present disclosure, a semiconductor package structure is provided. The semiconductor package structure includes: a first substrate; a processor module, arranged on a first plane of the first substrate and connected to the first substrate; a chip stack structure, arranged on the first plane of the first substrate and connected to the first substrate, where the first substrate is configured to transmit a first-type signal between the processor module and the chip stack structure; a signal adapter board, connected to the processor module and the chip stack structure, where the signal adapter board is configured to transmit a second-type signal between the processor module and the chip stack structure; and a second substrate, arranged parallel to the first substrate and connected to a second plane of the first substrate, where the second plane of the first substrate is parallel to and opposite to the first plane of the first substrate.

It should be understood that both the foregoing general description and the subsequent detailed description are exemplary and explanatory only and are not intended to limit the present disclosure.

### BRIEF DESCRIPTION OF DRAWINGS

The drawings, which are incorporated in and constitute a part of this specification, illustrate embodiments consistent with the present disclosure and, together with the specification, serve to explain the principles of the present disclosure. It is apparent that the drawings in the description below are only for some embodiments of the present disclosure, and for those of ordinary skill in the art, other drawings may be acquired according to the drawings without creative efforts.

FIG. 1 is a schematic structural diagram of a semiconductor package structure according to an exemplary embodiment of the present disclosure;

FIG. 2 is a schematic diagram of a chip stack structure according to an embodiment of the present disclosure;

FIG. 3 is a schematic diagram of a signal adapter board according to an embodiment of the present disclosure;

FIG. 4 is a schematic diagram of a signal adapter board according to another embodiment of the present disclosure;

FIG. 5 is a schematic diagram of a signal adapter board according to another embodiment of the present disclosure;

FIG. 6 is a schematic diagram of a semiconductor package structure according to another embodiment of the present disclosure; and

FIG. 7 is a schematic diagram of a semiconductor package structure according to yet another embodiment of the present disclosure.

### DESCRIPTION OF EMBODIMENTS

Exemplary embodiments will now be described more comprehensively with reference to the accompanying drawings. However, the exemplary embodiments may be implemented in many different forms and should not be construed as limited to the examples set forth herein; on the contrary, these embodiments are provided such that the present disclosure will be more comprehensive and complete, and will fully convey the concepts of the exemplary embodiments to those skilled in the art. The described characteristics, structures, or features may be combined in any suitable manner in one or more embodiments. In the following description, many specific details are provided to give a full understanding of the embodiments of the present disclosure. However, those skilled in the art will recognize that the technical solutions of the present disclosure may be practiced by omitting one or more of the specific details, or by employing other methods, components, devices, steps, and the like. In other instances, well-known technical solutions are not shown or described in detail to avoid overshadowing and obscuring aspects of the present disclosure.

In addition, the drawings are only schematic illustrations of the present disclosure, and the same reference numerals in the drawings represent the same or similar parts, and thus their repeated description will be omitted. Some of the block diagrams shown in the drawings are functional entities and do not necessarily correspond to physically or logically independent entities. These functional entities may be implemented in the form of software, or implemented in one or more hardware modules or integrated circuits, or implemented in different networks and/or processor devices and/or microcontroller devices.

The exemplary embodiments of the present disclosure are described in detail below with reference to the drawings.

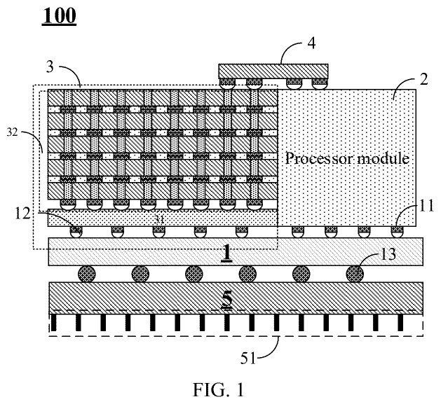

FIG. 1 is a schematic structural diagram of a semiconductor package structure according to an exemplary embodiment of the present disclosure.

Referring to FIG. 1, a semiconductor package structure 100 may include:
a first substrate 1;
a processor module 2, arranged on a first plane of the first substrate 1 and connected to the first substrate 1;
a chip stack structure 3, arranged on the first plane of the first substrate 1 and connected to the first substrate 1, where the first substrate 1 is configured to transmit a first-type signal between the processor module 2 and the chip stack structure 3;
a signal adapter board 4, connected to the processor module 2 and the chip stack structure 3, where the signal adapter board 4 is configured to transmit a second-type signal between the processor module 2 and the chip stack structure 3; and
a second substrate 5, arranged parallel to the first substrate 1 and connected to a second plane of the first substrate 1, where the second plane of the first substrate 1 is parallel to and opposite to the first plane of the first substrate 1.

In the embodiments of the present disclosure, the chip stack structure 3 is, for example, a high bandwidth memory (High Bandwidth Memory, HBM). The technical solutions of the embodiments of the present disclosure may be applied to 2.5D packaging of an HBM and a controller. The 2.5D packaging of the HBM and the controller means that the controller and the HBM chip are separately manufactured, and then are connected together through a silicon interposer (silicon interposer, i.e., the first substrate 1). This packaging technology can improve performance such as the bandwidth and memory capacity of the chip and power efficiency, and reduce the size, weight, and power consumption of the chip. Since the controller and the HBM chip are separately manufactured, different processes and materials can be used for better performance and power efficiency.

In one embodiment, the first substrate 1 may be a printed circuit board (PCB) or a silicon interposer (silicon interposer). The first substrate 1 may include a first base substrate (not shown), and a first upper insulating dielectric layer (not shown) and a first lower insulating dielectric layer (not shown) located on the upper surface and the lower surface of the first base substrate, respectively. The first base substrate may be a silicon substrate, a germanium substrate, a germanium-silicon substrate, a silicon carbide substrate, a silicon-on-insulator (Silicon On Insulator, SOI) substrate, a germanium-on-insulator (Germanium On Insulator, GOI) substrate, or the like, or may be a substrate including another element semiconductor or compound semiconductor, for example, a glass substrate or a group III-V compound substrate (for example, a gallium nitride substrate or a gallium arsenide substrate), or may be a stack structure, for example, Si/SiGe, or may be another epitaxial structure, for example, a silicon-germanium-on-insulator (SGOI), or the like. The first upper insulating dielectric layer and the first lower insulating dielectric layer may be solder mask layers. For example, the materials of the first upper insulating dielectric layer and the first lower insulating dielectric layer may be green solder resist. In the embodiments of the present disclosure, the surface corresponding to the first upper insulating dielectric layer is referred to as the first plane (the upper surface in FIG. 1) of the first substrate 1, and the surface corresponding to the first lower insulating dielectric layer is referred to as the second plane (the lower surface in FIG. 1) of the first substrate 1.

The first substrate 1 is connected to both the processor module 2 and the chip stack structure 3, providing a path for signal communication between the processor module 2 and the chip stack structure 3. Manufacturing costs of the first substrate 1 are relatively high due to the position and function of the first substrate 1. As requirements for storage performance and processing performance increase, the sizes of the processor module 2 and the chip stack structure 3 increase, and the size of the first substrate 1 also increases, which significantly increases the difficulty and cost of manufacturing and production.

In the 2.5D packaging of the HBM and the controller, the signals transmitted between the HBM and the controller mainly include input/output signals (IO signals) and power supply signals, and are usually transmitted through a physical layer (Physical Layer, PHY) on the silicon interposer. The number of IO signals is large, the transmission lines are relatively dense, and the line pitch (pitch) is relatively small, requiring the use of silicon-metal (silicon-metal) connection methods, which demand relatively high process requirements. The number of power supply signals is relatively small, the transmission lines are relatively thick, and the line pitch (pitch) is relatively large.

In the embodiments of the present disclosure, the first substrate 1 is configured to only transmit the first-type signal, so as to reduce the area of the first substrate 1 and lower the manufacturing process requirements for the first substrate 1. The first-type signals may be signals with a relatively small number and a relatively large wiring width. In one embodiment, the first-type signals are power supply signals. The number of the power supply signals is relatively small and the wiring width is relatively large. When the first substrate 1 is configured to only transmit the power signals, the area of the first substrate 1 is significantly reduced, and the processing cost of the first substrate 1 is also reduced accordingly, thereby reducing the manufacturing cost of the semiconductor package structure 100.

In one embodiment, the signal routing in the first substrate 1 may be completed by using a redistribution layer (Redistribution Layer, RDL) process, and the conventional silicon-metal (silicon-metal) wiring does not need to be arranged in the first substrate 1, thereby reducing the manufacturing cost of the first substrate 1. The cost of wiring using RDL (Redistribution Layer) technology is lower than that of silicon-metal (silicon-metal) wiring, because the RDL technology can add a layer of metal lines on a wafer to achieve a higher line density and a more complex wiring structure, while the silicon-metal wiring needs to etch metal lines on the wafer, resulting in relatively high manufacturing costs. In addition, the RDL technology can use thinner metal layers, thereby reducing the amount and cost of metal, while the silicon-metal wiring needs to use relatively thick metal layers, resulting in relatively high costs. Third, the RDL technology can achieve higher manufacturing efficiency and shorter manufacturing cycle, because it can complete the wiring of multiple chips on the wafer at one time, while the silicon-metal wiring requires individual etching and wiring for each chip, resulting in a relatively long manufacturing cycle. Finally, the RDL technology can achieve higher reliability and lower failure rate, because it can reduce the distance and crossing between metal lines, thereby reducing the interference and failure rate between the lines, while the silicon-metal wiring is prone to interference and failure between the lines.

Therefore, wiring using the RDL technology has lower costs compared to silicon-metal wiring, and can further achieve a higher line density, a more complex wiring structure, higher manufacturing efficiency, and a lower fault rate. Wiring is completed only on the first substrate 1 by using the RDL process, so that the manufacturing cost of the first substrate 1 can be significantly reduced, thereby reducing the overall manufacturing costs of the semiconductor package structure 100. Configuring the first substrate 1 to only transmit the first-type signal also provides a prerequisite for completing the wiring through the RDL process, because the signal line routing for the second-type signal cannot be completed through the RDL process.

It can be understood that although the above embodiments take the first-type signal as the power supply signal and the second-type signal as the input/output signal as examples, in other embodiments of the present disclosure, any signal that can meet the wiring requirements through the RDL wiring process may be referred to as the first-type signal, and other signals transmitted between the processor module 2 and the chip stack structure 3 except the first-type signal may be collectively referred to as the second-type signal. The present disclosure does not limit the specific names of the first-type signal and the second-type signal.

With continued reference to FIG. 1, the first substrate 1 achieves a signal connection with the processor module 2 through processor connection bumps 11, achieves a signal connection with the chip stack structure 3 through stack structure connection bumps 12, and achieves a signal connection with the second substrate 5 through substrate connection bumps 13.

The substrate connection bumps 13 are formed on the second plane of the first substrate 1, and the substrate connection bumps 13 can electrically connect the first substrate 1 to the second substrate 5. The second substrate 5 is configured to be connected to a main board of an electronic device through a main board connecting structure 51. Therefore, while providing signal paths for the processor module 2 and the chip stack structure 3, the first substrate 1 can further receive, from the second substrate 5, at least one of to-be-processed data, power signals, and ground signals from the main board, or provide control commands and data signals that are sent by the processor module 2 to the second substrate 5, thereby providing the control commands and the data signals to the main board.

The substrate connection bump 13 includes a conductive material. In the embodiments of the present disclosure, the substrate connection bump 13 is a solder ball. It can be understood that the shape of the substrate connection bump according to the embodiments of the present disclosure is used as a specific and feasible embodiment in the embodiments of the present disclosure, and does not constitute a limitation on the present disclosure. The substrate connection bump may also have other shapes and structures. The number, spacing, and position of the substrate connection bumps are not limited to any particular arrangement and may be variously modified.

The processor module 2 arranged on the first plane of the first substrate 1 is provided with an independent package, and the processor module 2 is connected to the first plane of the first substrate 1 through the processor connection bumps 11. The processor module 2 is configured to perform various computing tasks, such as logical operations, arithmetic operations, and control flow. It may be an independent integrated circuit (SOC, System on a Chip, system on chip), or may also be a complex system composed of a plurality of functional units. In one embodiment, the processor module 2 may be a graphics processing unit (Graphics Processing Unit, GPU).

The chip stack structure 3 arranged on the first plane of the first substrate 1 includes a first semiconductor chip 31 and a second semiconductor chip stack structure 32. In one embodiment, the stack structure connection bumps 12 configured to be connected to the first substrate 1 are formed on one surface of the first semiconductor chip 31. The first semiconductor chip 31 is electrically connected to the first substrate 1 through the stack structure connection bumps 12, and the first substrate 1 supplies power to the first semiconductor chip 31 in a wired manner and performs signal exchange.

Materials of the processor connection bump 11 and the stack structure connection bump 12 may include, for example, at least one of aluminum, copper, nickel, tungsten, platinum, and gold. In some other embodiments, the first substrate 1, the processor module 2, and the chip stack structure 3 may also be connected by soldering, pins, or other manners, which is not particularly limited in the present disclosure. However, since the first substrate 1 is configured to only transmit the first-type signal, the first substrate 1, the processor module 2, and the chip stack structure 3 may be connected using the method (for example, soldering) with the lowest process requirements among available connection methods, thereby further reducing costs.

In one embodiment, when the first semiconductor chip 31 in the chip stack structure 3 is arranged on the first substrate 1, as shown in FIG. 1, the process is simple, and there is a gap between the first semiconductor chip 31 and the first substrate 1, so that the heat dissipation effect of the first semiconductor chip 31 can be improved. In this case, the stack structure connection bump 12 and the processor connection bump 11 are horizontal in the first direction.

In another embodiment, the stack structure connection bump 12 may also be arranged in the groove (not shown) on the first substrate 1 to improve the structural stability and reduce the package height of the semiconductor package structure. In addition, the first semiconductor chip 31 in the chip stack structure 3 may also be partially arranged in the groove, so that the chip stack structure 3 is partially embedded into the first substrate 1, thereby further improving the structural stability and reducing the package height of the semiconductor package structure. In this case, the stack structure connection bump 12 is lower than the processor connection bump 11 in the first direction.

In yet another embodiment, both the chip stack structure 3 and the processor module 2 may be provided with corresponding grooves (not shown) on the first substrate 1, and both the stack structure connection bump 12 and the processor connection bump 11 are arranged in the corresponding grooves, so as to improve the structural stability and reduce the package height of the semiconductor package structure. In addition, the chip stack structure 3 and the processor module 2 may also be partially arranged in the corresponding grooves, so that both the chip stack structure 3 and the processor module 2 are partially embedded into the first substrate 1, thereby further improving the structural stability and reducing the package height of the semiconductor package structure. In such a case, the stack structure connection bump 12 and the processor connection bump 11 are still horizontal in the first direction.

Regardless of the relative positional relationship, the stack structure connection bump 12 and the processor connection bump 11 achieve the transmission of the first-type signal through the first substrate 1. In addition, the stack structure connection bump 12 and the processor connection bump 11 may also be connected to the substrate connection bump 13 through wires (not shown) in the first substrate 1. In this way, the first semiconductor chip 31 and the processor module 2 can exchange information with the second substrate 5 and the main board through the substrate connection bump 13.

The signal adapter board 4 is connected to the processor module 2 and the chip stack structure 3, and is configured to transmit a second-type signal between the processor module and the chip stack structure. The signal adapter board 4 may be implemented, for example, through a bridge die (Bridge Die) or another medium entity (for example, a PCB board) that can achieve signal transmission. The signal adapter board 4 simultaneously connects the processor module 2 and the chip stack structure 3, establishing a bridge between the processor module 2 and the chip stack structure 3, such that the processor module and the chip stack structure can communicate and exchange data with each other.

The signal adapter board 4 is provided with a plurality of transistors and other electronic elements to perform processing such as amplification, filtering, and conversion on two or more input signals, and output the signals to the processor module 2 or the chip stack structure 3. In addition, the signal adapter board 4 is provided with two interfaces, and the two interfaces are connected to the processor module 2 and the chip stack structure 3, respectively. Each interface can be configured to receive data and transmit data. That is, at least two interfaces for connecting the processor module 2 and the chip stack structure 3, the path configured to transmit data, and the signal processing circuit configured to perform processing such as amplification, filtering, and conversion on the input signals are arranged in the signal adapter board 4.

Among the signals transmitted between the processor module 2 and the chip stack structure 3, signals that have relatively high requirements for signal line manufacturing are referred to as second-type signals, for example, various signals that need to be transmitted using the silicon-metal connection method. Due to the relatively low cost and relatively small area of the silicon-metal connection achieved by the bridge die, providing the silicon-metal connection in the bridge die (the signal adapter board 4) instead of the first substrate 1 can effectively reduce the manufacturing cost of the overall package structure.

In one embodiment, the signal adapter board 4 can achieve bidirectional communication between the processor module 2 and the chip stack structure 3, and can transmit data to both the processor module 2 and the chip stack structure 3. In another embodiment, the signal adapter board 4 only has a unidirectional transmission function for transmitting data from the processor module 2 to the chip stack structure 3 or for transmitting data from the chip stack structure 3 to the processor module 2.

Regardless of the unidirectional transmission or the bidirectional transmission, in the embodiments of the present disclosure, the signal adapter board 4 is configured to only transmit the second-type signal. Different from the first-type signal, the second-type signal may be signals with a relatively large number, a relatively small line width, relatively dense routing, and relatively high requirements on the manufacturing process. In one embodiment of the present disclosure, the second-type signal includes input/output signals, and the data signals include, but are not limited to, a control address signal (Commond/Address, CA signal), a data queue signal (Data Queue, DQ), and other auxiliary control signals, such as a clock signal (CLK), various types of enable signals (Enable), and the like. When the signal adapter board 4 is achieved by the bridge die, more precise processing can be performed, and the signal adapter board can be used to transmit signals that have relatively high requirements for the manufacturing process. Since the signal adapter board 4 is configured only for the transmission of part of the signals and has a limited area, the use of the signal adapter board 4 to transmit the second-type signals with relatively high costs can effectively reduce the manufacturing cost of the package structure, compared with transmitting all the signals through the high-cost first substrate 1.

It should be noted that, in the embodiments of the present disclosure, the sum of the first-type signals and the second-type signals is all signals transmitted between the processor module 2 and the chip stack structure 3. The signals transmitted between the processor module 2 and the chip stack structure 3 are classified into the first-type signals and the second-type signals, and the first substrate 1 with a relatively high cost and the signal adapter board 4 with a relatively low cost are used to transmit the first-type signals with relatively low process requirements and a relatively small number and the second-type signals with relatively high process requirements and a relatively large number, respectively, so that the signal interconnection cost between the processor module 2 and the chip stack structure 3 can be significantly reduced, thereby reducing the overall cost of the semiconductor package structure 100.

In one embodiment, the transmission path of the second-type signal may be fabricated by using a small chip, which serves as a bridge die to connect the processor module 2 and the chip stack structure 3 during assembly. Other connections are led out by using the FO process, resulting in a package cube (cube) formed by combining the processor module 2 and the chip stack structure 3. Subsequently, substrate packaging is performed (using the first substrate 1 and the second substrate 5 to complete the packaging). The FO process refers to a fiber optic coupling device manufacturing process. A micro optical element is manufactured on a silicon wafer by using the photolithography technology, and then the optical element is coupled to the optical fiber, to achieve the transmission and processing of optical signals.

In the embodiments of the present disclosure, the signal transmission function and the power supply function are respectively achieved by using the signal adapter board 4 and the first substrate 1, and the signal adapter board 4 and the first substrate 1 are manufactured using different processes, so that the production and cost pressure of the silicon interposer (the first substrate 1) can be effectively reduced. In addition, since the bridge die (the signal adapter board 4) used for the signal connection can be made very small, and the DPW (dies per wafer, the number of dies that can be produced per wafer) is relatively high, the cost of signal interconnection between the processor module 2 and the chip stack structure 3 can be very effectively reduced.

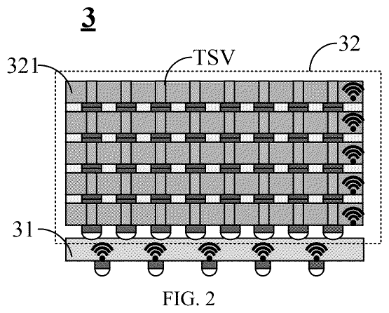

FIG. 2 is a schematic diagram of a chip stack structure according to an embodiment of the present disclosure.

Referring to FIG. 2, the chip stack structure 3 may include:
a first semiconductor chip 31, arranged parallel to the first substrate 1 and connected to the first plane of the first substrate 1; and
a second semiconductor chip stack structure 32, located on the first semiconductor chip 31 and including a plurality of second semiconductor chips 321 stacked in sequence, where each second semiconductor chip 321 is arranged parallel to the first substrate 1, and the plurality of second semiconductor chips 321 stacked in sequence achieve the signal connection through a through silicon via structure (TSV) perpendicular to the first substrate 1.

In an exemplary embodiment of the present disclosure, the first semiconductor chip 31 is, for example, a logic die (Logic Die, also referred to as a base chip), and the second semiconductor chip stack structure 32 includes a DRAM chip (also referred to as a core chip).

The second semiconductor chip stack structure 32 is, for example, a high bandwidth memory (High Band width Memory, HBM). The HBM technology is a major representative product of the development of DRAM from traditional 2D to three-dimensional 3D, marking the beginning of the three-dimensional path for DRAM. Chip stacking is mainly performed by using through silicon via (Through Silicon Via, TSV) technology, thereby increasing the throughput and overcoming the bandwidth limitation in a single package. Several DRAM dies are vertically stacked, and the dies are connected using the TSV technology. From a technical perspective, the HBM makes full use of space and reduces the area, aligning well with the development trend of miniaturization and integration in the semiconductor industry. In addition, the HBM breaks through the bottlenecks in memory capacity and bandwidth, and is regarded as a new-generation DRAM solution. In the second semiconductor chip stack structure 32, each second semiconductor chip 321 is a DRAM chip.

In the embodiment shown in FIG. 2, the second semiconductor chips 321 are sequentially stacked in parallel (P-Stack) on the first semiconductor chip 31, and the plurality of second semiconductor chips 321 are connected to each other through a plurality of TSVs perpendicular to the first substrate 1. At least one TSV penetrates through all the second semiconductor chips 321 to achieve the data transmission between the plurality of second semiconductor chips 321. The arrangement position and arrangement number of TSVs configured to perform data transmission between the second semiconductor chips 321 may be determined based on the design of the second semiconductor chips 321.

In some embodiments, the second semiconductor chips 321 and the first semiconductor chip 31 may also communicate with each other through TSVs. In some other embodiments, the communication between the first semiconductor chip 31 and the second semiconductor chip stack structure 32 may also be achieved wirelessly. For example, a wireless coil (not shown) is arranged in each DRAM in the second semiconductor chip stack structure 32, and correspondingly, a corresponding wireless coil is arranged at a position corresponding to the above coil on the first semiconductor chip 31. The wireless communication is performed between the first semiconductor chip 31 and the second semiconductor chip stack structure 32, which can effectively solve the communication difficulties caused by the increasing number of stacked layers of the second semiconductor chips 321. At the same time, the number of TSVs (configured to transmit signals) is reduced, and the process difficulty is lowered.

In addition to that, as shown in FIG. 2, the second semiconductor chips 321 are sequentially stacked in parallel (P-Stack) on the first semiconductor chip 31. In one embodiment, the plurality of second semiconductor chips 321 in the second semiconductor chip stack structure 32 may also be vertically stacked side by side (V-Stack) on the first semiconductor chip 31. In this way, the first semiconductor chip 31 and the second semiconductor chip 321 may communicate with each other in a wireless manner, thereby effectively solving the communication difficulties caused by the increasing number of stacked layers of the second semiconductor chips 321 when the plurality of second semiconductor chips are sequentially stacked in parallel (P-Stack) on the first semiconductor chip 31. That is, by configuring the stacking direction of the second semiconductor chip stack structure 32 to be perpendicular to the surface of the first semiconductor chip 31, each second semiconductor chip 321 may have the same communication distance from the first semiconductor chip 31, thereby overcoming the communication delay caused by multi-layer stacking.

In one embodiment, a first wireless communication module (not shown) is arranged on the first semiconductor chip 31, a second wireless communication module (not shown) is arranged on the signal adapter board 4, and the first semiconductor chip 31 is configured to communicate with the second wireless communication module through the first wireless communication module to control the signal transmission process of the signal adapter board 4. The communication mode between the first wireless communication module and the second wireless communication module is, for example, WIFI.

The first semiconductor chip 31 may be in wireless communication with each second semiconductor chip 321 and the signal adapter board 4.

The first semiconductor chip 31 may control the signal adapter board 4 through the wireless communication to receive or stop receiving the second-type signal, start or stop processing the second-type signal, and transmit or stop transmitting the second-type signal, and may control the signal adapter board 4 to process part or all of the second-type signals, or may also control the signal adapter board 4 to process the second-type signals using part or all of the processing methods among all processing methods. Meanwhile, the first semiconductor chip 31 may control each second semiconductor chip 321 to receive the data transmitted by the signal adapter board 4 and process the data transmitted by the signal adapter board 4, or control each second semiconductor chip 321 to process the data and transmit the processed data to the chip stack structure 3 through the signal adapter board 4.

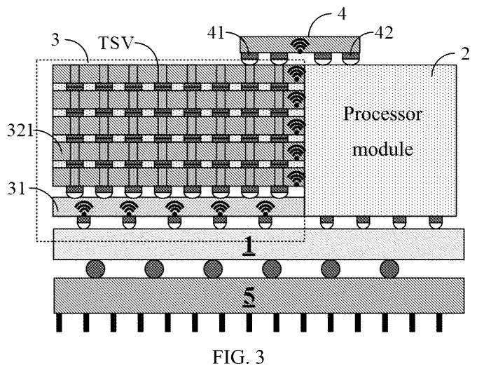

FIG. 3 is a schematic diagram of a signal adapter board according to an embodiment of the present disclosure.

Referring to FIG. 3, in one embodiment, the signal adapter board 4 is arranged parallel to the first substrate 1.

In this case, the signal adapter board 4 may be arranged to connect the surface of the processor module 2 distal to the first substrate 1 and the surface of the chip stack structure 3 distal to the first substrate 1. In FIG. 3, the signal adapter board 4 is arranged on the top layer of the processor module 2 and the chip stack structure 3, and the first substrate 1 is arranged on the bottom layer of the processor module 2 and the chip stack structure 3.

Since the signal adapter board 4 is configured to transmit the relatively precise second-type signal, placing the signal adapter board 4 on the top layer can reduce the crosstalk and noise impact of the wiring of the bottom-layer first substrate 1 on the second-type signal, and reduce signal interference. In addition, providing the signal adapter board 4 on the top layer facilitates heat dissipation. In this case, the FO process may be used when the RDL process is used in the bottom-layer first substrate 1, and costs are also relatively low.

In the embodiment shown in FIG. 3, the chip stack structure 3 is provided with a plurality of TSVs perpendicular to the first substrate 1, a first signal pin 41 connected to the TSV is arranged on the surface of the chip stack structure 3 distal to the first substrate 1, a second signal pin 42 is arranged on the surface of the processor module 2 distal to the first substrate 1, the first plane of the signal adapter board 4 is connected to the first signal pin 41 and the second signal pin 42, and both the first signal pin 41 and the second signal pin 42 are configured to transmit the first-type signal.

In one embodiment, the first signal pin 41 is arranged on the side of the chip stack structure 3 proximal to the processor module 2, and the second signal pin 42 is arranged on the side of the processor module 2 proximal to the chip stack structure 3, such that the area of the signal adapter board 4 is as small as possible.

In this case, the first preset number of TSVs of the second semiconductor chip stack structure 32 may be configured to achieve the signal transmission communication between the first semiconductor chip 31 and the signal adapter board 4. Correspondingly, when the first signal pin 41 is arranged on the side of the chip stack structure 3 proximal to the processor module 2, in the chip stack structure 3, the first preset number of TSVs connected to the first signal pin 41 and configured to transmit the second-type signal are arranged proximal to the processor module 2. In other embodiments of the present disclosure, the first preset number of TSVs and the first signal pin 41 may also have other position schemes. In a special case, the signal adapter board 4 may be expanded to connect the first preset number of TSVs located in the middle or other parts of the second semiconductor chip stack structure 32, and those skilled in the art may determine the pins and dimensions of the signal adapter board 4 based on the actual TSV configuration, which is not particularly limited in the present disclosure.

Similarly, the first wireless communication module may be further arranged on the first semiconductor chip 31, and the second wireless communication module may be further arranged on the signal adapter board 4. The first semiconductor chip 31 communicates with the second wireless communication module through the first wireless communication module to control the signal transmission process of the signal adapter board 4.

That is, in the embodiment shown in FIG. 3, the communication mode between the signal adapter board 4 and the first semiconductor chip 31 may be a wired manner only (through TSV communication) or a combination of wired and wireless manners.

When the signal adapter board 4 and the first semiconductor chip 31 communicate with each other in a wired manner only or in a combination of wired and wireless manner, since the first preset number of TSVs transmitting the signal penetrates through the plurality of second semiconductor chips 321, each second semiconductor chip 321 may directly receive the second-type signal transmitted by the signal adapter board 4 from the first preset number of TSVs according to the control command of the first semiconductor chip 31, or directly transmit the second-type signal to the signal adapter board 4 based on the first preset number of TSVs. In this case, the signal adapter board 4 may be controlled by the first semiconductor chip 31, or may be controlled by the processor module 2 together with the first semiconductor chip 31.

In another embodiment, each second semiconductor chip 321 may not directly exchange signals with the signal adapter board 4, and the first preset number of TSVs may be configured to only transmit signals between the signal adapter board 4 and the first semiconductor chip 31. In this case, the first semiconductor chip 31 uniformly receives the second-type signals from the signal adapter board 4 through the first preset number of TSVs, and then transmits data to the second semiconductor chip 321 through other TSVs; or, uniformly receives the data from each second semiconductor chip 321, and then transmits the data to the signal adapter board 4 through the first preset number of TSVs.

The specific signal transmission control scheme may be set according to actual needs, which is not particularly limited in the present disclosure.

When substrate packaging is performed, the connection between the first substrate 1 and the processor module 2 and the chip stack structure 3 may be first completed, then the connection between the processor module 2, the signal adapter board 4, and the chip stack structure 3 is completed, and finally the connection between the first substrate 1 and the second substrate 5 is completed.

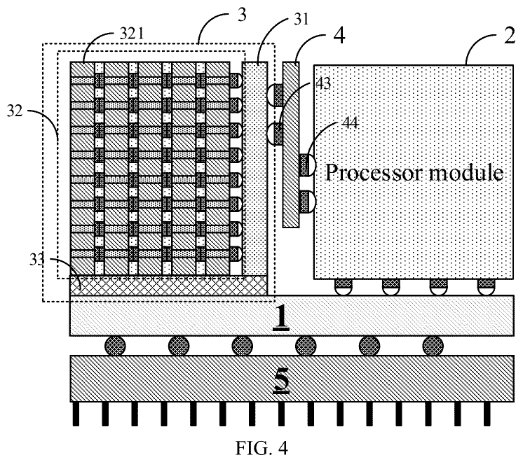

FIG. 4 is a schematic diagram of a signal adapter board according to another embodiment of the present disclosure.

Referring to FIG. 4, in another embodiment, the signal adapter board 4 is arranged perpendicular to the first substrate 1.

In the embodiment shown in FIG. 4, the signal adapter board 4 is arranged between the processor module 2 and the chip stack structure 3, the first plane of the signal adapter board 4 is connected to the surface of the processor module 2 proximal to the chip stack structure 3, the second plane of the signal adapter board 4 is connected to the surface of the chip stack structure 3 proximal to the processor module 2, and the first plane and the second plane of the signal adapter board 4 are opposite to and parallel to each other.

In this case, the chip stack structure 3 includes the first semiconductor chip 31 arranged perpendicular to the first substrate 1 and the plurality of second semiconductor chips 321 stacked in parallel on the first semiconductor chip 31, third signal pins 43 are arranged on the surface of the first semiconductor chip 31 proximal to the processor module 2, fourth signal pins 44 are arranged on the surface of the processor module 2 proximal to the chip stack structure 3, the first plane of the signal adapter board 4 is connected to the third signal pins 43, and the second plane of the signal adapter board 4 is connected to the fourth signal pins 44.

When the stacking direction of the chip stack structure 3 is parallel to the first substrate 1, the first semiconductor chip 31 is perpendicular to the first substrate 1 and proximal to the processor module 2. Therefore, the signal adapter board 4 perpendicular to the first substrate 1 and parallel to the first semiconductor chip 31 can achieve the signal transmission between the processor module 2 and the first semiconductor chip 31 through the third signal pins 43 and the fourth signal pins 44. In this case, the chip stack structure 3 further includes an adhesive film layer 33. The adhesive film layer 33 is located between the first semiconductor chip 31 and the second semiconductor chip stack structure 32, and is configured to bond the first semiconductor chip 31 and the second semiconductor chip stack structure 32, and to enhance the adhesion between the first semiconductor chip and the second semiconductor chip stack structure, thereby improving the firmness of the semiconductor package structure. The adhesive film layer 33 is implemented, for example, through a die-attach adhesive film.

It should be noted that, in this embodiment, during the substrate packaging, the connection between the processor module 2, the signal adapter board 4, and the chip stack structure 3 needs to be completed first, then the connection between the first substrate 1 and the processor module 2 and the chip stack structure 3 is completed, and finally the connection between the first substrate 1 and the second substrate 5 is completed.

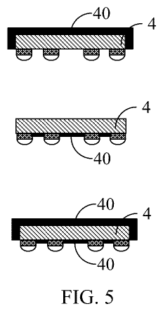

FIG. 5 is a schematic diagram of a signal adapter board according to another embodiment of the present disclosure.

Referring to FIG. 5, in any embodiment of the present disclosure, the first surface and/or the second surface of the signal adapter board 4 may be provided with a signal shielding layer 40, and the first surface and the second surface are arranged opposite to each other.

The signal shielding layer 40 is, for example, an anti-signal interference coating or a signal shielding film, which helps the signal adapter board 4 avoid external signal interference and provides better protection for the second-type signal.

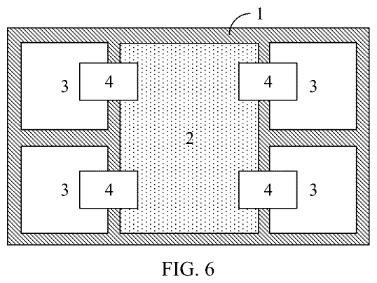

FIG. 6 is a schematic diagram of a semiconductor package structure according to another embodiment of the present disclosure.

Referring to FIG. 6, in the embodiments of the present disclosure, the number of processor modules 2 arranged on the first substrate 1 may be one or more, and the number of chip stack structures 3 may also be one or more. When there are a plurality of chip stack structures 3, the chip stack structures may be arranged around one or more processor modules 2. In this case, the first substrate 1 connects the plurality of chip stack structures 3 and the processor module 2, resulting in a relatively large area.

In this case, one signal adapter board 4 may be arranged between each chip stack structure 3 and the processor module 2 to transmit the second-type signal, and the signal line routing of the first-type signal is completed only in the first substrate 1 by using the RDL process, thereby reducing the manufacturing cost of the first substrate 1. It can be seen from the embodiment shown in FIG. 6 that, when the area of the first substrate 1 is relatively large, reducing the process requirements for the first substrate 1 can significantly reduce the packaging cost.

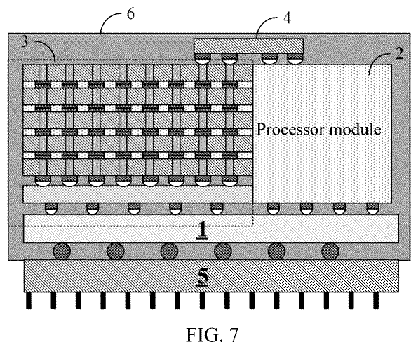

FIG. 7 is a schematic diagram of a semiconductor package structure according to yet another embodiment of the present disclosure.

Referring to FIG. 7, in yet another embodiment, the semiconductor package structure further includes a package compound structure 6 located on the second substrate 5 and configured to wrap the first substrate 1, the signal adapter board 4, the processor module 2, and the chip stack structure 3.

In some embodiments, after the connections of the first substrate 1, the signal adapter board 4, the processor module 2, the chip stack structure 3, and the second substrate 5 are completed, the package compound structure 6 may be further formed to package the semiconductor package structure 100 as a whole.

The package compound structure 6 includes a silicon-containing compound. The silicon-containing compound may be spin-on glass (SOG), silicon-containing spin-on dielectric (SOD), or other silicon-containing spin-on materials. By forming the package compound structure 6, with the material of the package compound structure 6 including a silicon-containing compound, it can not only reduce the warpage problem of the second semiconductor chip stack structure 32, but also package the semiconductor package structure 100 as a whole, thereby improving the overall structural strength.

In the embodiments of the present disclosure, by using the signal adapter board 4 to transmit the second-type signal with relatively high process requirements, the manufacturing requirements for the first substrate 1 can be reduced, and the cost of the overall package structure can be reduced.

In the embodiments of the present disclosure, by using the signal adapter board together with the first substrate to complete the signal transmission between the processor module and the chip stack structure, and configuring the first substrate to only transmit the first-type signal, the manufacturing cost of the first substrate (silicon interposer) can be significantly reduced, thereby lowering the overall packaging cost.

Those skilled in the art will readily conceive other embodiments of the present disclosure after considering the specification and practicing the invention disclosed herein. The present application is intended to cover any variations, uses, or adaptations of the present disclosure, and these variations, uses, or adaptations follow the general principles of the present disclosure and include the common knowledge or conventional techniques in the art that are not disclosed herein. The specification and embodiments are to be regarded as exemplary only, and the true scope and concept of the present disclosure are indicated by the claims.

What is claimed is:

1. A semiconductor package structure, comprising:
a first substrate;
a processor module, arranged on a first plane of the first substrate and connected to the first substrate;
a chip stack structure, arranged on the first plane of the first substrate and connected to the first substrate, wherein the first substrate is configured to transmit a first-type signal between the processor module and the chip stack structure;
a signal adapter board, connected to the processor module and the chip stack structure, wherein the signal adapter board is configured to transmit a second-type signal between the processor module and the chip stack structure; and
a second substrate, arranged parallel to the first substrate and connected to a second plane of the first substrate, wherein the second plane of the first substrate is parallel to and opposite to the first plane of the first substrate.

2. The semiconductor package structure of claim 1, wherein the first-type signal comprises a power supply signal, and the second-type signal comprises an input/output signal.

3. The semiconductor package structure of claim 1, wherein the chip stack structure comprises:
a first semiconductor chip, arranged parallel to the first substrate and connected to the first plane of the first substrate;
a second semiconductor chip stack structure, located on the first semiconductor chip and comprising a plurality of second semiconductor chips stacked in sequence, wherein each of the plurality of second semiconductor chips is arranged parallel to the first substrate, and the plurality of second semiconductor chips stacked in sequence achieve a signal connection through through silicon vias (TSVs) perpendicular to the first substrate.

4. The semiconductor package structure of claim 3, wherein a first preset number of TSVs of the second semiconductor chip stack structure are configured to achieve signal transmission between the first semiconductor chip and the signal adapter board.

5. The semiconductor package structure of claim 3, wherein a first wireless communication module is arranged on the first semiconductor chip, a second wireless communication module is arranged on the signal adapter board, and the first semiconductor chip is configured to communicate with the second wireless communication module through the first wireless communication module to control a signal transmission process of the signal adapter board.

6. The semiconductor package structure of claim 1, wherein the signal adapter board is arranged parallel to the first substrate, and the signal adapter board is connected to a surface of the processor module distal to the first substrate and a surface of the chip stack structure distal to the first substrate.

7. The semiconductor package structure of claim 6, wherein the chip stack structure is provided with a plurality of TSVs perpendicular to the first substrate, a first signal pin connected to the TSVs is arranged on the surface of the chip stack structure distal to the first substrate, a second signal pin is arranged on the surface of the processor module distal to the first substrate, a first plane of the signal adapter board is connected to the first signal pin and the second signal pin, and both the first signal pin and the second signal pin are configured to transmit the first-type signal.

8. The semiconductor package structure of claim 7, wherein the first signal pin is arranged on a side of the chip stack structure proximal to the processor module, and the second signal pin is arranged on a side of the processor module proximal to the chip stack structure.

9. The semiconductor package structure of claim 1, wherein the signal adapter board is arranged perpendicular to the first substrate.

10. The semiconductor package structure of claim 9, wherein the signal adapter board is arranged between the processor module and the chip stack structure, a first plane of the signal adapter board is connected to a surface of the processor module proximal to the chip stack structure, a second plane of the signal adapter board is connected to a surface of the chip stack structure proximal to the processor module, and the first plane and the second plane of the signal adapter board are opposite to and parallel to each other.

11. The semiconductor package structure of claim 10, wherein the chip stack structure comprises a first semiconductor chip arranged perpendicular to the first substrate and a plurality of second semiconductor chips stacked in parallel on the first semiconductor chip, a third signal pin is arranged on a surface of the first semiconductor chip proximal to the processor module, a fourth signal pin is arranged on the surface of the processor module proximal to the chip stack structure, the first plane of the signal adapter board is connected to the third signal pin, and the second plane of the signal adapter board is connected to the fourth signal pin.

12. The semiconductor package structure of claim 1, wherein a signal shielding layer is arranged on a first surface and/or a second surface of the signal adapter board, and the first surface and the second surface are arranged opposite to each other.

13. The semiconductor package structure of claim 1, wherein signal routing in the first substrate is completed by a redistribution layer process.

14. The semiconductor package structure of claim 3, wherein the first semiconductor chip comprises a logic chip, and the second semiconductor chip stack structure comprises a DRAM chip.

15. The semiconductor package structure of claim 1, further comprising:
a package compound structure, located on the second substrate and configured to wrap the first substrate, the signal adapter board, the processor module, and the chip stack structure.

16. The semiconductor package structure of claim 1, wherein the first substrate is configured to only transmit the first-type signal.

17. The semiconductor package structure of claim 1, wherein the signal adapter board is configured to only transmit the second-type signal.

18. The semiconductor package structure of claim 2, wherein the chip stack structure comprises:
a first semiconductor chip, arranged parallel to the first substrate and connected to the first plane of the first substrate;
a second semiconductor chip stack structure, located on the first semiconductor chip and comprising a plurality of second semiconductor chips stacked in sequence, wherein each of the plurality of second semiconductor chips is arranged parallel to the first substrate, and the plurality of second semiconductor chips stacked in sequence achieve a signal connection through through silicon vias (TSVs) perpendicular to the first substrate.

19. The semiconductor package structure of claim 4, wherein a first wireless communication module is arranged on the first semiconductor chip, a second wireless communication module is arranged on the signal adapter board, and the first semiconductor chip is configured to communicate with the second wireless communication module through the first wireless communication module to control a signal transmission process of the signal adapter board.
